(19) United States
(12) Patent Application Publication
(10) Pub. No.: US 2012/0199888 A1
(43) Pub. Date: Aug. 9, 2012

(54) FIN FIELD-EFFECT TRANSISTOR STRUCTURE

(75) Inventors: Sheng-Huei Dai, Taitung County (TW); Rai-Min Huang, Taipei City (TW); Chen-Hua Tsai, Hsinchu County (TW); Chun-Hsien Lin, Tainan County (TW)

(73) Assignee: UNITED MICROELECTRONICS CORPORATION, HSINCHU (TW)

(21) Appl. No.: 13/364,445

(22) Filed: Feb. 2, 2012

Related U.S. Application Data
(62) Division of application No. 13/023,581, filed on Feb. 9, 2011, now abandoned.

(51) Int. Cl. H01L 29/78

(52) U.S. Cl. 257/288; 257/E29.255

(57) ABSTRACT

A fin field-effect transistor structure includes a silicon substrate, a fin channel, a gate insulator layer and a gate conductor layer. The fin channel is formed on a surface of the silicon substrate, wherein the fin channel has at least one slant surface. The gate insulator layer formed on the slant surface of the fin channel. The gate conductor layer formed on the gate insulator layer.

### CROSS-REFERENCE TO RELATED APPLICATION

This application is a divisional of an application Ser. No. 13/023,581, filed on Feb. 09, 2011, now pending. The entirety of each of the above-mentioned patent applications is hereby incorporated by reference herein and made a part of this specification.

### FIELD OF THE INVENTION

The present invention relates to a fin field-effect transistor structure, and more particularly to a fin field-effect transistor structure applied to a semiconductor manufacturing process. The present invention also relates to a manufacturing process of such a fin field-effect transistor structure.

### BACKGROUND OF THE INVENTION

Nowadays, as integrated circuits are increasingly developed toward miniaturization, the conventional transistor structure whose channel and substrate are coplanar usually fails to meet the practical requirements. Especially, the performance of the conventional transistor structure in high-speed circuitry is unsatisfied because the current driving capability is insufficient. For solving these drawbacks, a fin field-effect transistor (FinFET) structure has been disclosed.

FIG. 1 is a schematic view illustrating a FinFET structure according to the prior art. Like the typical FET structure, the FinFET structure of FIG. 1 comprises a substrate 10, a source 11, a drain 12, a gate insulator layer 13 and a gate conductor layer 14. However, since a channel (not shown) between the source 11 and the drain 12 is covered by the gate insulator layer 13 and the gate conductor layer 14, plural surfaces are utilized to provide more current paths. In other words, the FinFET structure has better current driving capability than the typical FET structure. However, the performance of the FinFET structure needs to be further optimized by improving the configurations and the manufacturing process of the FinFET structure.

### SUMMARY OF THE INVENTION

In accordance with another aspect, the present invention provides a fin field-effect transistor structure. The fin field-effect transistor structure includes a silicon substrate, a fin channel, a gate insulator layer and a gate conductor layer. The fin channel is formed on a surface of the silicon substrate, wherein the fin channel has at least one slant surface. The gate insulator layer is formed on the slant surface of the fin channel. The gate conductor layer is formed on the gate insulator layer.

In an embodiment, the surface of the silicon substrate is a (100) crystal plane, a top surface of the fin channel is a (100) crystal plane, and the fin channel extends along a <100> direction. The slant surface is a (110) crystal plane or a (111) crystal plane, and the overall length of the slant surface is greater than the height of the fin channel. In this situation, the fin channel is a p-type fin channel.

In an embodiment, the surface of the silicon substrate is a (110) crystal plane, a top surface of the fin channel is a (110) crystal plane, and the fin channel extends along a <100> direction. The slant surface is a (100) crystal plane, and the overall length of the slant surface is greater than the height of the fin channel. In this situation, the fin channel is an n-type fin channel.

In an embodiment, a second fin channel with a polarity opposite to the fin structure is further formed on the silicon substrate, wherein the second fin channel has at least one vertical sidewall.

In an embodiment, the fin channel has a sandglass-shaped cross section with a wide top region, a wide bottom region and a narrow middle region.

In an embodiment, an included angle between the slant surface and a normal vector of the silicon substrate is 54.7 degrees.

In an embodiment, the gate insulator layer and the gate conductor layer are further formed over the top surface of the fin channel.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic view illustrating a FinFET structure according to the prior art;

FIGS. 2A, 2B and 2C schematically illustrate some crystal orientations;

FIGS. 2D and 2E schematically illustrate a fin channel of a FinFET structure according to the present invention;

FIGS. 3A, 3B, 3C and 3D schematically illustrate some steps of a process of manufacturing a FinFET structure according to an embodiment of the present invention; and

FIGS. 4A, 4B and 4C schematically illustrate some steps of a process of manufacturing a FinFET structure according to another embodiment of the present invention; and

FIGS. 5A, 5B, 5C, 5D, 5E, 5F and 5G schematically illustrate some steps of a process of manufacturing a FinFET structure according to a further embodiment of the present invention.

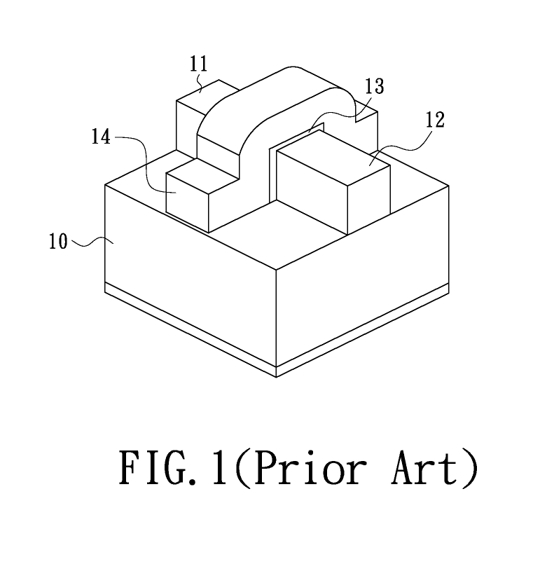

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

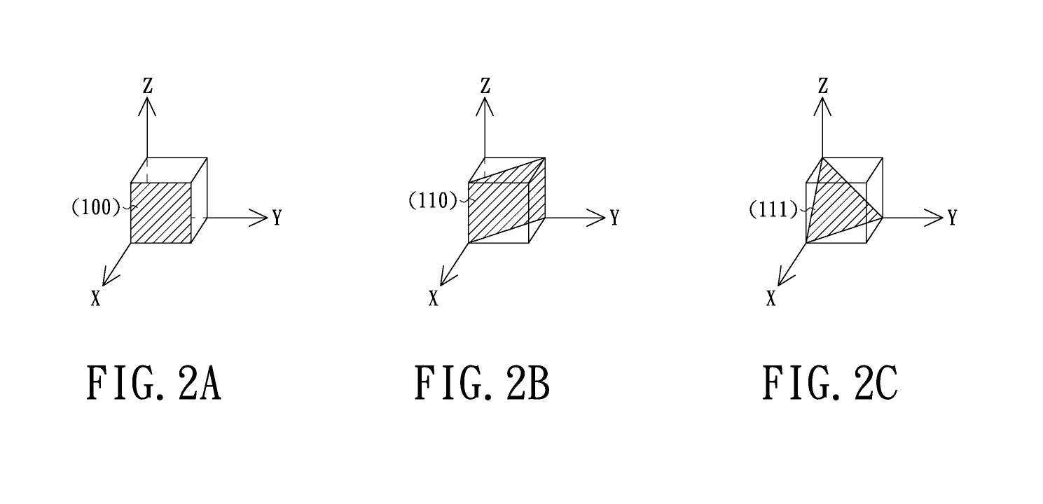

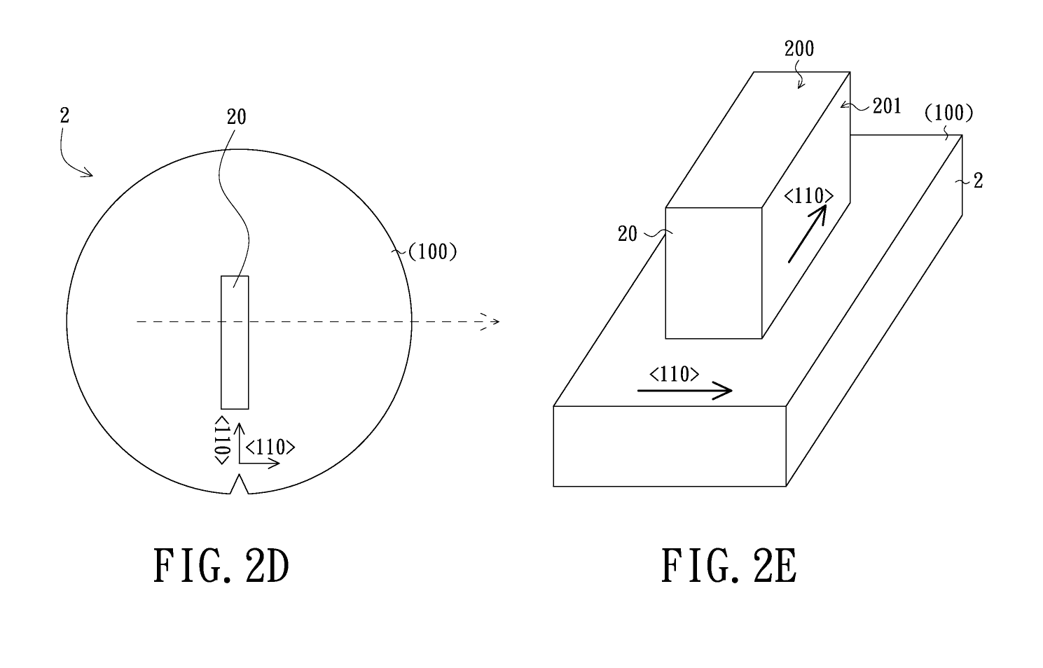

Since a silicon crystal has a diamond crystal lattice, the silicon crystal has many crystal orientations. FIGS. 2A, 2B and 2C schematically illustrate some crystal orientations. In FIG. 2A, an equivalent crystallographic orientation of a crystal plane (100) is represented as <100>. In FIG. 2B, an equivalent crystallographic orientation of a crystal plane (110) is represented as <110>. In FIG. 2C, an equivalent crystallographic orientation of a crystal plane (111) is represented as <111>.

As known, the highest electron mobility of the n-channel metal-oxide-semiconductor (NMOS) appears in the <110> direction on the (100) crystal plane; and the highest hole mobility of the p-channel metal-oxide-semiconductor (PMOS) appears in <110> direction of the (110) crystal plane. Since the common wafer used in the process of manufacturing a FinFET structure has a (100) crystal plane and a <110> notch direction, the wafer having the (100) crystal plane and the <110> notch direction is used for manufacturing a FinFET structure in this embodiment. FIG. 2D is a schematic top view illustrating a fin channel of a FinFET structure according to the present invention. FIG. 2E is a schematic cutaway view illustrating the fin channel of the FinFET structure taken along the dotted line. The fin channel 20 is directly formed on the (100) crystal plane of the wafer 2 by aligning the notch direction. The top surface 200 of the fin channel 20 is a (100) crystal plane, and the sidewall 201 of the fin channel 20 is a (110) crystal plane, and the fin channel 20 extends along the <110> direction. Due to the fin channel 20, the highest hole mobility of the PMOS is achievable. However, in a case that the fin channel 20 is applied to the NMOS, the electron mobility of the NMOS is deteriorated. In other word, such fin channel needs to be further improved.

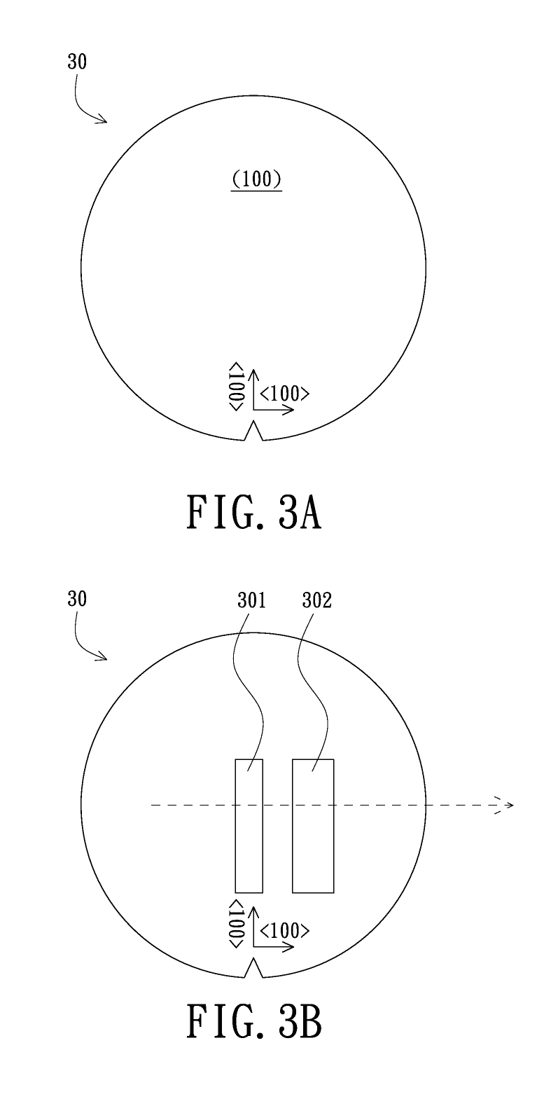

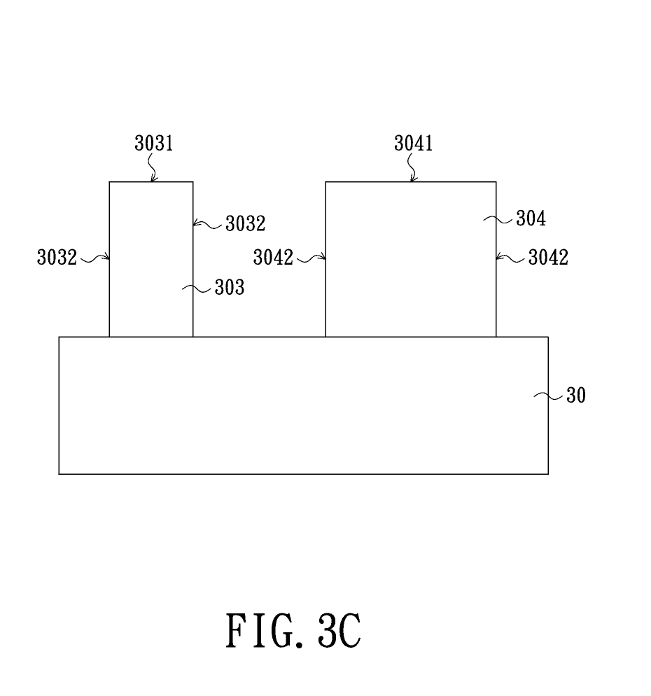

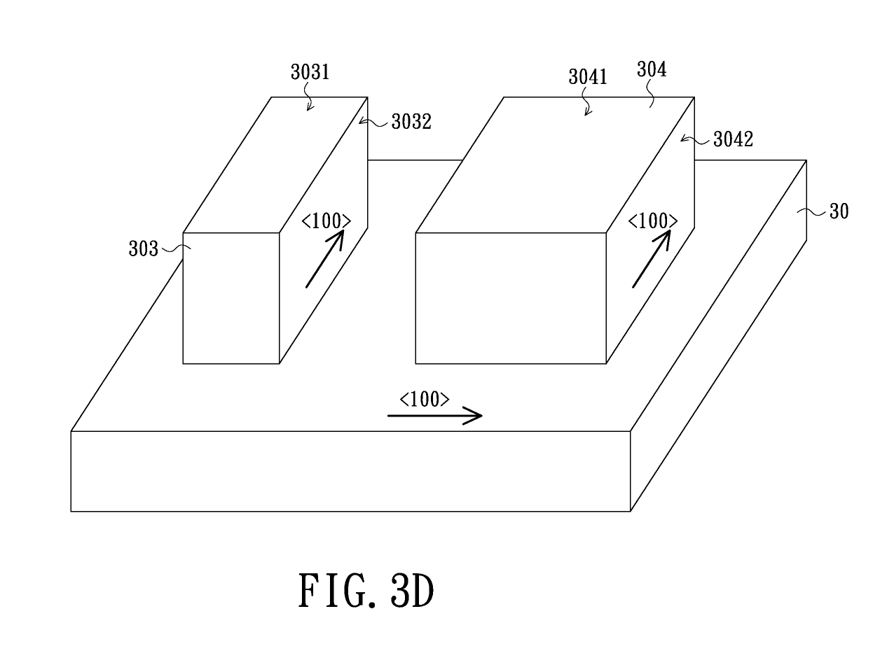

FIGS. 3A, 3B, 3C and 3D schematically illustrate some steps of a process of manufacturing a FinFET structure according to an embodiment of the present invention. Firstly, as shown in FIG. 3A, a wafer 30 having a (100) crystal plane and a <100>notch direction is provided. The wafer 30 is a silicon wafer or a silicon-on-insulator (SOI) wafer. Then, a shown in FIG. 3B, hard masks 301 and 302 are formed on the surface of the (100) crystal plane of the wafer 30. Then, an etching process is performed to form an n-type fin channel 303 and a p-type fin channel 304, which extend along the <100> direction (see FIGS. 3C and 3D). FIG. 3C is a schematic cross-sectional view illustrating the fin channels of the FinFET structure of FIG. 3B taken along the dotted line. FIG. 3D is a schematic cutaway view illustrating the fin channels of the FinFET structure of FIG. 3B taken along the dotted line. The top surface 3031 of the n-type fin channel 303 and the top surface 3041 of the p-type fin channel 304 are (100) crystal planes. The vertical sidewall 3032 of the n-type fin channel 303 and the vertical sidewall 3042 of the p-type fin channel 304 are (100) crystal planes, and both extend along the <100> direction. By means of these fin channels, the electron mobility of the NMOS of the FinFET structure is not degraded and the improvement on the hole mobility of the PMOS is about 10%-15%. Consequently, the purpose of the present invention is achieved. Since the top surfaces 3031 and 3041 and the vertical sidewalls 3032 and 3042 are all (100) crystal planes, the manufacturing process of this embodiment is suitable to fabricate a tri-gate FinFET structure or a double-gate FinFET structure.

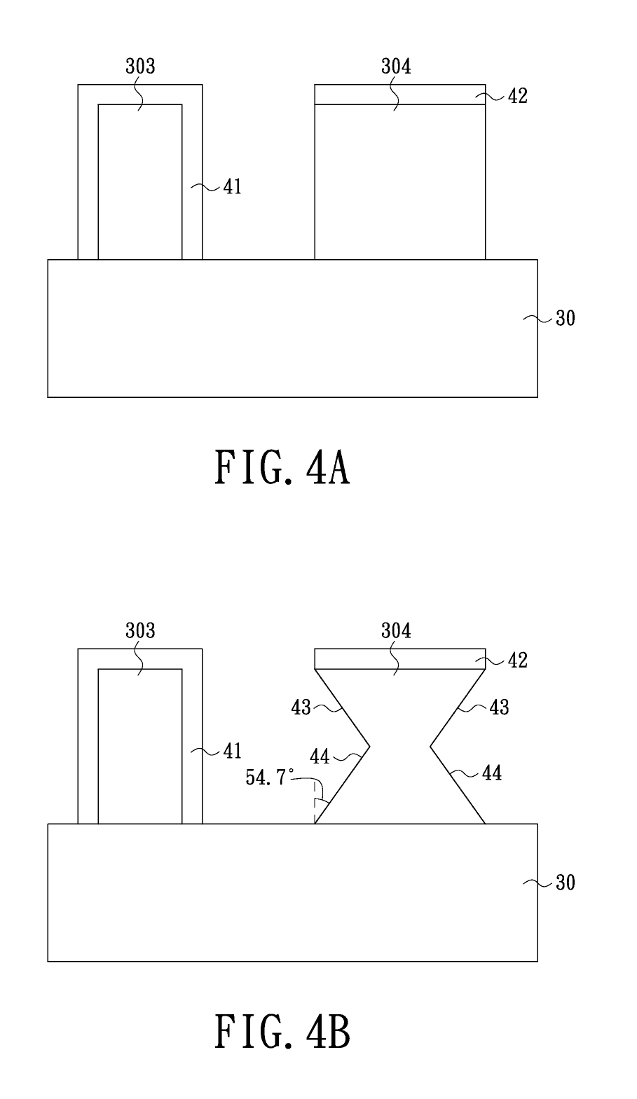

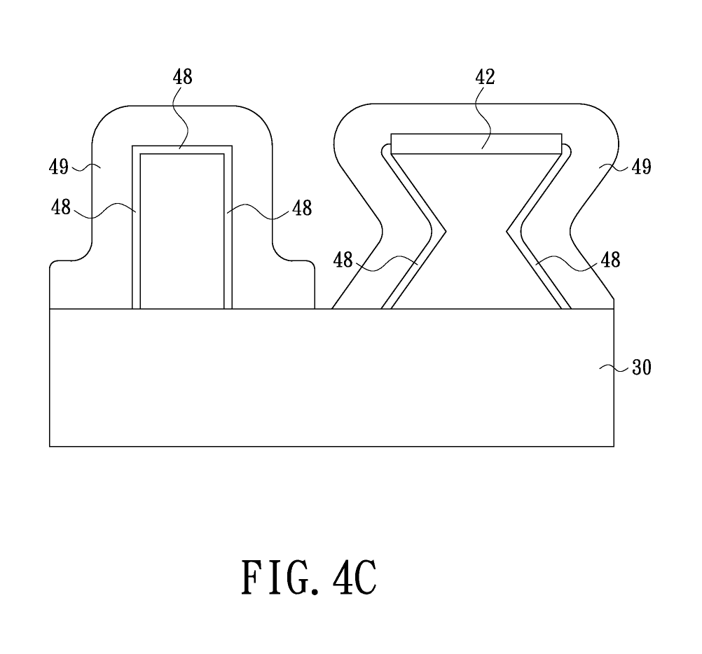

FIGS. 4A, 4B and 4C schematically illustrate some steps of a process of manufacturing a FinFET structure according to another embodiment of the present invention. The purpose of this embodiment is to further improve the n-type fin channel 303 and the p-type fin channel 304 as shown in FIG. 3C. Firstly, as shown in FIG. 4A, the top surface 3031 and the vertical sidewall 3032 of the n-type fin channel 303 are completely covered by a hard mask 41. Whereas, the top surface 3041 of the p-type fin channel 304 is covered by a hard mask 42, but the vertical sidewall 3042 is exposed. Then, as shown in FIG. 4B, an anisotropic etching process is performed to etch the exposed vertical sidewall 3042 to form two slant surfaces 43 and 44. In an embodiment, the anisotropic etching process is a wet etching process using an alkaline solution as an etchant. The alkaline solution is a tetramethylammonium hydroxide (TMAH) solution, an ammonium hydroxide (NH₄OH) solution, a sodium hydroxide (NaOH) solution, a potassium hydroxide (KOH) solution, an ethylenediamine pyrocatechol (EDP) solution, or any other possible alkaline solution. By selecting a suitable etchant or adjusting the concentration of the etchant, the slant surfaces 43 and 44 may be formed at different etching rates. Since the anisotropic etching rates on the (110) crystal plane and the (111) crystal plane are different, the slant surfaces 43 and 44 may be fabricated as the (110) crystal planes or the (111) crystal planes by a well-known Wulff-Jaccodine process.

After the vertical sidewall 3042 of the p-type fin channel 304 is anisotropically etched by using the hard mask 42 as an etching mask, the slant surfaces 43 and 44 are formed. In accordance with a key feature of the present invention, the overall length of the slant surfaces 43 and 44 is greater than the height of the vertical sidewall 3042. That is, the overall length of the slant surfaces is greater than the height of the p-type fin channel 304. Whereas, the n-type fin channel 303 maintains the original cross-sectional shape. On the other hand, due to the slant surfaces 43 and 44, the p-type fin channel 304 has a sandglass-shaped cross section with a wide top region, a wide bottom region and a narrow middle region. In this situation, the p-type fin channel 304 has increased effective channel width. Afterward, a gate insulator layer 48 and a gate conductor layer 49 are formed on the n-type fin channel 303 and the p-type fin channel 304, thereby producing the FinFET structure of FIG. 4C. Moreover, due to good surface adhesive ability, an atomic layer deposition (ALD) process may be performed to successfully fill the gate insulator layer 48 and the gate conductor layer 49 in the space between the slant surfaces 43 and 44. Since the top surface of the p-type fin channel 304 is a (100) crystal plane but the slant surfaces of the p-type fin channel 304 are (110) or (111) crystal planes, the manufacturing process of this embodiment is suitable to fabricate a double-gate FinFET structure.

In such way, sufficient effective channel width will be provided without the need of increasing the height of the p-type fin channel. The lower aspect ratio is good for fabricating the gate conductor layer in the subsequent process. As a consequence, the manufacturing process is simplified. For example, the fin channel of the conventional FinFET structure has an aspect ratio greater than 1 (e.g. 2-4). Whereas, according to the present invention, the aspect ratio of the sandglass-shaped fin channel of the FinFET structure is reduced to about 0.578. Moreover, the short channel effect and the drain induced barrier lowering (DIBL) of the sandglass-shaped fin channel are reduced when compared with the conventional vertical-sidewall channel.

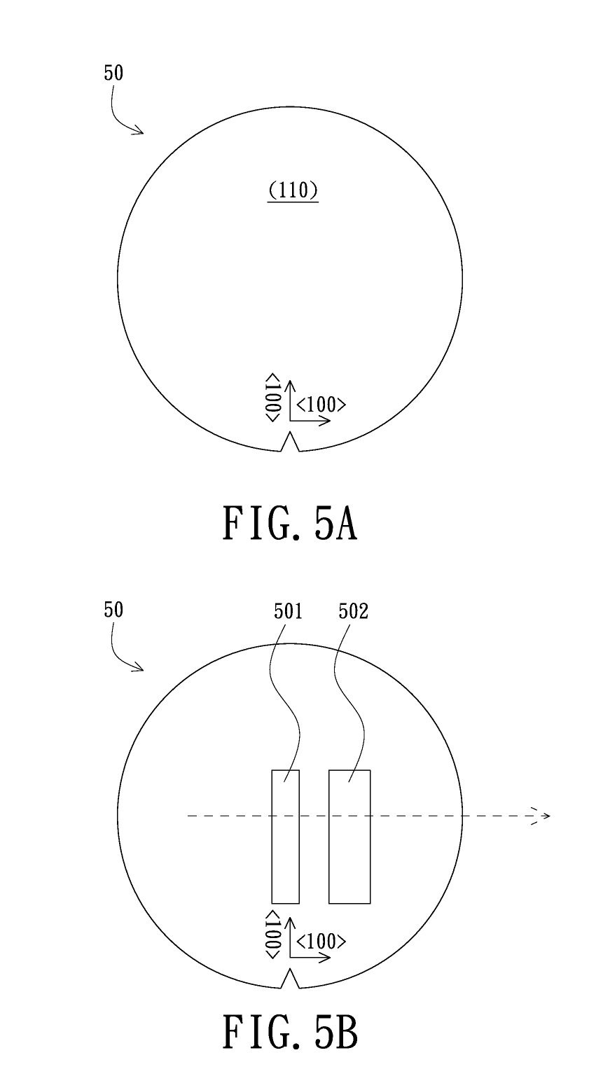

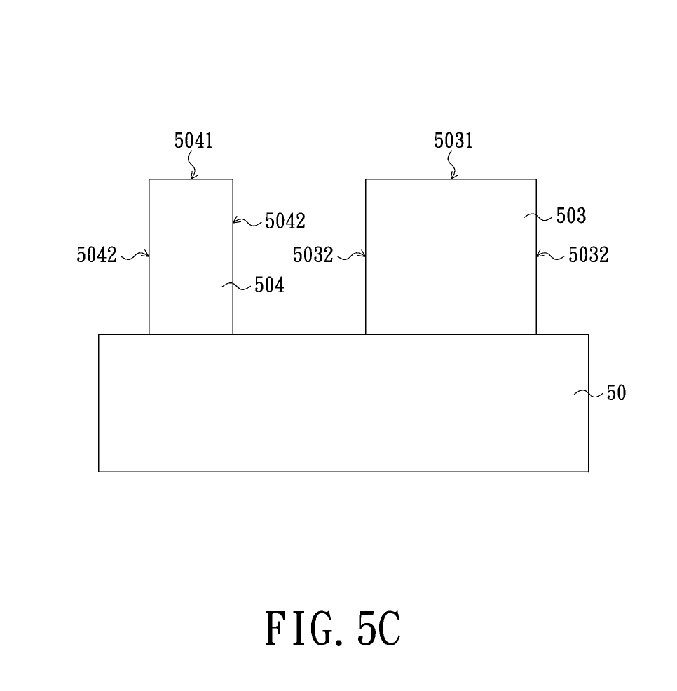

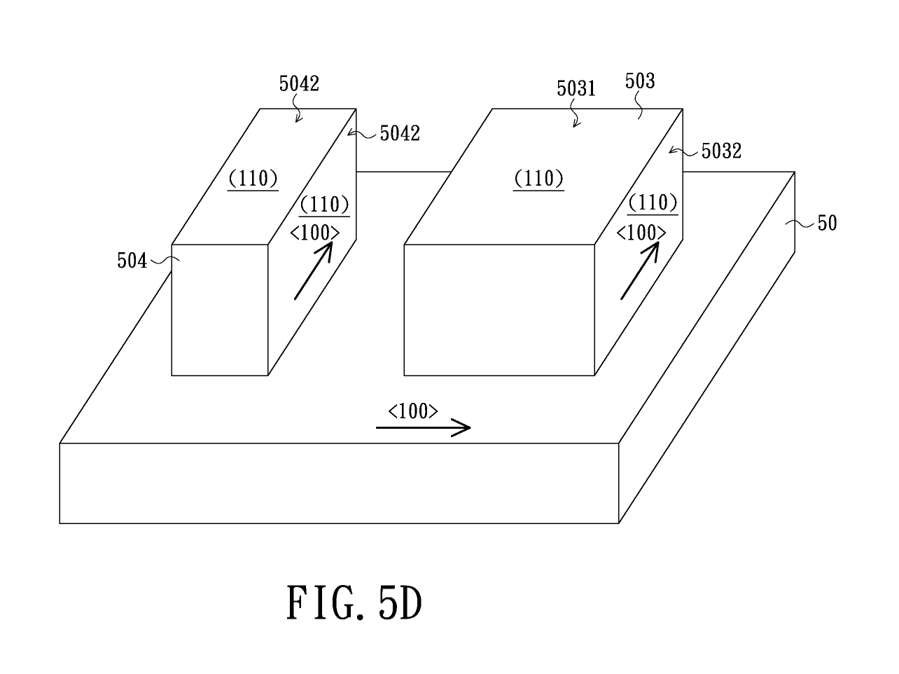

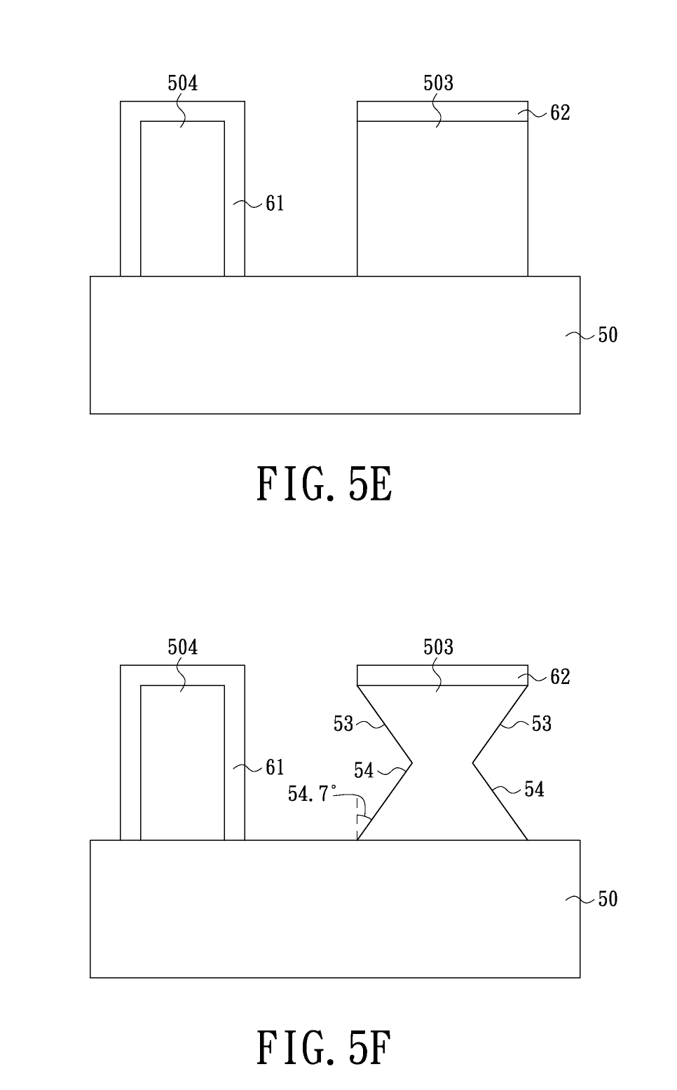

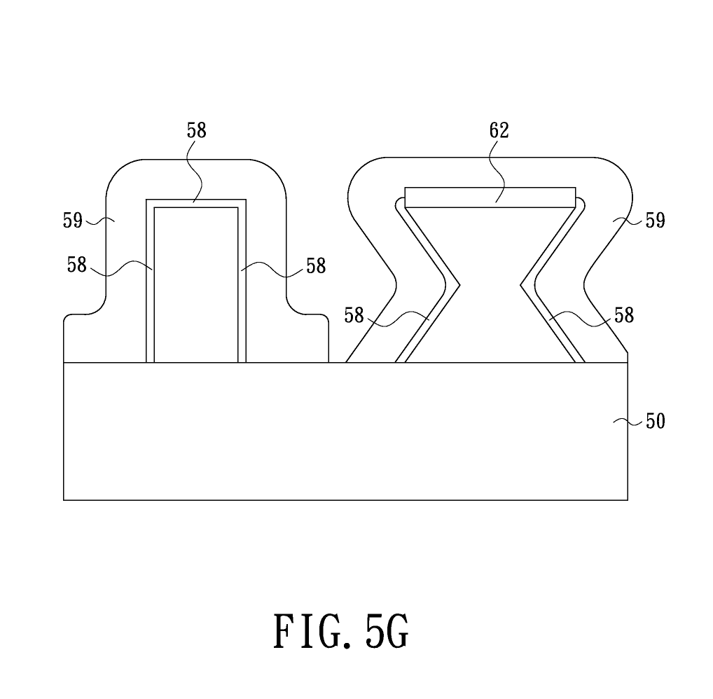

Alternatively, a sidewall etching process may be performed to etch the n-type fin channel. FIGS. 5A, 5B, 5C, 5D, 5E, 5F and 5G schematically illustrate some steps of a process of manufacturing a FinFET structure according to a further embodiment of the present invention. Firstly, as shown in FIG. 5A, a wafer 50 having a (110) crystal plane and a <100> notch direction is provided. The wafer 50 is a silicon wafer or a silicon-on-insulator (SOI) wafer. Then, a shown in FIG. 5B, hard masks 501 and 502 are formed on the surface of the (110) crystal plane of the wafer 50. Then, an etching process is performed to form an n-type fin channel 503 and a p-type fin channel 504, which extend along the <100>direction (see FIGS. 5C and 5D). FIG. 5C is a schematic cross-sectional view illustrating the fin channels of the FinFET structure of FIG. 5B taken along the dotted line. FIG. 5D is a schematic cutaway view illustrating the fin channels of the FinFET structure of FIG. 5B taken along the dotted line. The top surface 5031 of the n-type fin channel 503 and the top surface 5041 of the p-type fin channel 504 are (110) crystal planes. The vertical sidewall 5032 of the n-type fin channel 503 and the vertical sidewall 5042 of the p-type fin channel 504 are (110) crystal planes, and both extend along the <100> direction. Since all of the top surface and the vertical sidewalls are (110) crystal planes, the manufacturing process of this embodiment is suitable to fabricate a tri-gate FinFET structure or a double-gate FinFET structure.

However, as shown in FIG. 5E, if the top surface 5041 and the vertical sidewall 5042 of the p-type fin channel 504 are further completely covered by a hard mask 61. Whereas, the top surface 5031 of the n-type fin channel 503 is covered by a hard mask 62, but the vertical sidewall 5032 of the n-type fin channel 503 is exposed. Then, as shown in FIG. 5F, an anisotropic etching process is performed to etch the exposed vertical sidewall 5032 to form two slant surfaces 53 and 54. In an embodiment, the anisotropic etching process is a wet etching process using an alkaline solution as an etchant. The alkaline solution is a tetramethylammonium hydroxide (TMAH) solution, an ammonium hydroxide (NH₄OH) solution, a sodium hydroxide (NaOH) solution, a potassium hydroxide (KOH) solution, an ethylenediamine pyrocatechol (EDP) solution, or any other possible alkaline solution. By selecting a suitable etchant or adjusting the concentration of the etchant, the slant surfaces 53 and 54 may be formed at different etching rates. Consequently, the slant surfaces 53 and 54 may be fabricated as the (100) crystal planes by a well-known Wulff-Jaccodine process.

After the vertical sidewall 5032 of the n-type fin channel 503 is anisotropically etched, the slant surfaces 53 and 54 are formed. In addition, the overall length of the slant surfaces 53 and 54 is greater than the height of the vertical sidewall 5032. That is, the overall length of the slant surfaces is greater than the height of the n-type fin channel 503.

Whereas, the p-type fin channel 504 maintains the original cross-sectional shape. On the other hand, due to the slant surfaces 53 and 54, the n-type fin channel 503 has a sandglass-shaped cross section, wherein the included angle between the slant surface and a normal vector of the silicon substrate is 54.7 degrees. In this situation, the n-type fin channel 503 has increased effective channel width. Afterward, a gate insulator layer 58 and a gate conductor layer 59 are formed on the n-type fin channel 503 and the p-type fin channel 504, thereby producing the FinFET structure of FIG. 5G. Moreover, due to good surface adhesive ability, an atomic layer deposition (ALD) process may be performed to successfully fill the gate insulator layer 58 and the gate conductor layer 59 in the space between the slant surfaces 53 and 54. Since the top surface is a crystal plane (100) but the slant surfaces are (100) crystal planes, the manufacturing process of this embodiment is suitable to fabricate a double-gate FinFET structure.

In such way, sufficient effective channel width will be provided without the need of increasing the height of the n-type fin channel. The lower aspect ratio is good for fabricating the gate conductor layer in the subsequent process. As a consequence, the manufacturing process is simplified. For example, the fin channel of the conventional FinFET structure has an aspect ratio greater than 1 (e.g. 2-4). Whereas, according to the present invention, the aspect ratio of the sandglass-shaped fin channel of the FinFET structure is reduced to about 0.578. Moreover, the short channel effect and the drain induced barrier lowering (DIBL) of the sandglass-shaped fin channel are reduced when compared with the conventional vertical-sidewall channel.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A fin field-effect transistor structure, comprising:
a silicon substrate;
a fin channel formed on a surface of the silicon substrate, wherein the fin channel has a sandglass-shaped cross section with a wide to region, a wide bottom region and a narrow middle region;
a gate insulator layer formed on the slant surface of the fin channel; and
a gate conductor layer formed on the gate insulator layer.

2. The fin field-effect transistor structure according to claim 1, wherein the surface of the silicon substrate is a (100) crystal plane, a top surface of the fin channel is a (100) crystal plane, and the fin channel extends along a <100> direction.

3. The fin field-effect transistor structure according to claim 2, wherein the slant surface is a (110) crystal plane or a (111) crystal plane, and the overall length of the slant surface is greater than the height of the fin channel.

4. The fin field-effect transistor structure according to claim 3, wherein the fin channel is a p-type fin channel.

5. The fin field-effect transistor structure according to claim 1, wherein the surface of the silicon substrate is a (110) crystal plane, a top surface of the fin channel is a (110) crystal plane, and the fin channel extends along a <100> direction.

6. The fin field-effect transistor structure according to claim 5, wherein the slant surface is a (100) crystal plane, and the overall length of the slant surface is greater than the height of the fin channel.

7. The fin field-effect transistor structure according to claim 6, wherein the fin channel is an n-type fin channel.

8. The fin field-effect transistor structure according to claim 1, wherein a second fin channel with a polarity opposite to the fin structure is further formed on the silicon substrate, wherein the second fin channel has at least one vertical sidewall.

9. (canceled)

10. The fin field-effect transistor structure according to claim 1, wherein an included angle between the slant surface and a normal vector of the silicon substrate is 54.7 degrees.

11. The fin field-effect transistor structure according to claim 1, wherein the gate insulator layer and the gate conductor layer are further formed over the top surface of the fin channel.
